(19) United States
(12) Patent Application Publication
(10) Pub. No.: US 2012/0319179 A1
(43) Pub. Date: Dec. 20, 2012

(54) METAL GATE AND FABRICATION METHOD THEREOF

(76) Inventors: Hsin-Fu Huang, Tainan City (TW); Zhi-Cheng Lee, Tainan City (TW); Chi-Mao Hsu, Tainan City (TW); Chin-Fu Lin, Tainan City (TW); Kun-Hsien Lin, Tainan City (TW); Tzung-Ying Lee, Ping-Tung County (TW); Min-Chuan Tsai, New Taipei City (TW)

(21) Appl. No.: 13/161,519

(22) Filed: Jun. 16, 2011

(51) Int. Cl. H01L 21/28; H01L 29/78

(52) U.S. Cl. 257/288; 438/592; 257/E29.255; 257/E21.19

(57) ABSTRACT

A metal gate includes a substrate, a gate dielectric layer, a work function metal layer, an aluminum nitride layer and a stop layer. The gate dielectric layer is located on the substrate. The work function metal layer is located on the gate dielectric layer. The aluminum nitride layer is located on the work function metal layer. The stop layer is located on the aluminum nitride layer.

### BACKGROUND OF THE INVENTION

1. Field of the Invention

The present invention relates generally to a metal gate and fabrication method thereof, and more specifically, to a stop layer in-situ forming on a work function metal layer, forming a metal gate structure, and a fabrication method thereof.

2. Description of the Prior Art

Poly-silicon is conventionally used as a gate electrode in semiconductor devices, such as the metal-oxide-semiconductor (MOS). However, with a trend toward scaling down the size of semiconductor devices, the conventional poly-silicon gate has faced problems such as inferior performance due to boron penetration and an unavoidable depletion effect which increases the equivalent thickness of the gate dielectric layer, reduces gate capacitance, and worsens a driving force of the devices. Therefore, work function metals have been used to replace the conventional poly-silicon gate, to act as the control electrodes suitable for use as the high-K gate dielectric layer.

In current processes, the metal gate would be exposed to the atmosphere or an oxygen-importing process would be performed after the work function metal layer is formed. Then, a titanium nitride layer is formed on the work function metal layer to stop metals on the work function metal layer, such as aluminum, diffusing downward. However, the work function metal layer is prone to be oxidized in the process thereby forming an oxide layer and resulting in the degradation of the work function metal layer. This affects the electrical quality of devices, such as MOS transistor, that apply the work function metal layer. For example, the work function of the NMOS transistor fabricated in said process would be up to 4.81 eV. Therefore, it is an important issue in the field to reduce the work function of the metal gate.

### SUMMARY OF THE INVENTION

The present invention provides a metal gate and fabrication method thereof, to reduce the thickness of the oxide layer generated by the oxidation of the work function metal layer and formed thereon, to diminish the work function of the work function metal layer, and improve the electrical quality of devices, such as MOS transistor, that apply the improved work function metal layer.

The present invention provides a metal gate including a substrate, a gate dielectric layer, a work function metal layer, an aluminum nitride layer and a stop layer. The gate dielectric layer is located on the substrate. The work function metal layer is located on the gate dielectric layer. The aluminum nitride layer is located on the work function metal layer. The stop layer is located on the aluminum nitride layer.

The present invention provides a fabricating method of a metal gate, the steps including: a gate dielectric layer is formed on a substrate. A work function metal layer is formed on the gate dielectric layer. A stop layer is formed in-situ on the work function metal layer.

The present invention provides a fabricating method of a metal gate, the steps including: a gate structure is formed on a substrate, wherein the gate structure includes a gate dielectric layer and a sacrificed gate located on the gate dielectric layer. An etching process is performed to remove the sacrificed gate. A work function metal layer is formed to replace the sacrificed gate. A stop layer is formed in-situ on the work function metal layer.

According to the above, the invention provides a metal gate and fabrication method thereof, wherein the stop layer is formed in-situ on the work function metal layer, therefore the thickness of the native oxide layer of the work function metal layer located between the work function metal layer and the stop layer can be decreased to be as small as possible. For example, the thickness of the oxide layer is less than 30% of the thickness of the work function metal layer. In a preferred embodiment, the thickness of the oxide layer can almost approach zero. That is, the metal gate structure formed by the metal gate process of this invention has lower work function compared with the prior art, thereby improving the electrical quality of the metal gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A-1B schematically depicts a cross-sectional view of a metal gate process according to a first embodiment of the present invention.

FIG. 2A-2E schematically depicts a cross-sectional view of a metal gate process according to a second embodiment of the present invention.

FIG. 3A-3B schematically depicts a cross-sectional view of a metal gate process according to a third embodiment of the present invention.

FIG. 4 schematically depicts a TEM cross-sectional view of a metal gate structure according to a preferred embodiment of the present invention.

### DETAILED DESCRIPTION

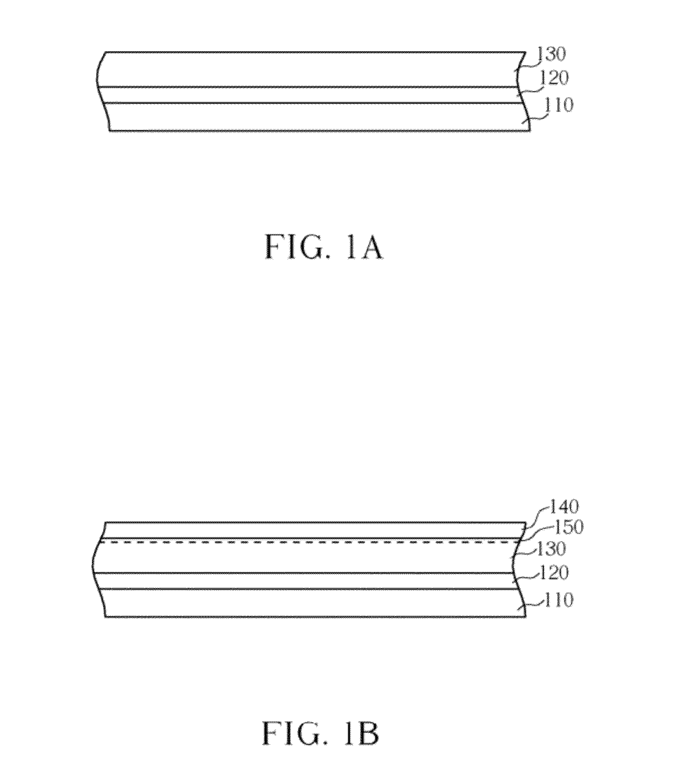

FIG. 1A-1B schematically depicts a cross-sectional view of a metal gate process according to the first embodiment of the present invention. Please refer to FIG. 1A-1B. As shown in FIG. 1A, a substrate 110 is provided and a gate dielectric layer 120 is formed on the substrate 110, wherein the substrate 110 may be a semiconductor substrate such as a silicon substrate, a silicon-containing substrate or a silicon-on-insulator (SOI) substrate, and the gate dielectric layer 120 may be a stack structure with a single layer or multilayered. Otherwise, a buffer interface layer (not shown) may be formed before the gate dielectric layer 120 is formed, to buffer and connect the substrate 110 and the gate dielectric layer 120, wherein the material of the buffer interface layer may be silicon dioxide. In this embodiment, the gate dielectric layer 120 may be, but is not limited to, a gate dielectric layer having a high-k dielectric constant, and the gate dielectric layer having a high-k dielectric constant may be metal oxide, such as hafnium oxide, zirconium oxide. For instance, the gate dielectric layer having a high-k dielectric constant may be selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁₋ₓO₃, PZT) and barium strontium titanate (BaₓSr₁₋ₓTiO₃, BST).

A work function metal layer 130 is formed on the gate dielectric layer 120. The metal gate 100 of this embodiment is applied to an NMOS transistor, so that the work function metal layer 130 of this embodiment is a titanium aluminum metal layer, but is not limited thereto. The titanium aluminum metal layer may be formed by processes such as Physical Vapor Deposition (PVD) or Atomic Layer Deposition (ALD). By applying Physical Vapor Deposition Process to form the titanium aluminum metal layer for example, the gate dielectric layer 120 may be formed by respectively sputtered aluminum and titanium in a specific ratio and then mixed aluminum and titanium into an aluminum titanium alloy by applying an annealing process, or the gate dielectric layer 120 may be also formed by sputtering aluminum titanium alloy with a desired ratio. After the gate dielectric layer 120 is formed, a barrier layer (not shown) may be selectively formed and then the work function metal layer 130 is formed, so that the barrier layer (not shown) is located between the gate dielectric layer 120 and the work function metal layer 130, to prevent the ingredients of the work function metal layer 130, such as aluminum, from diffusing into the gate dielectric layer 120, resulting in lower electrical quality of the metal gate 100. In one case, the barrier layer (not shown) may include a titanium nitride layer or a tantalum nitride layer etc, but is not limited thereto.

As shown in FIG. 1B, a stop layer 140 is formed in-situ on the work function metal layer 130. In this embodiment, the stop layer 140 is a titanium nitride layer, but is not limited thereto. Materials that can stop unnecessary ingredients of upper layers from diffusing downward may be materials of the stop layer 140 depending on processes. In other words, the metal gate would not be exposed to the atmosphere, and oxygen importing processes, such as an oxygen annealing process, would not be performed in the present invention instead of processes performed in the prior art. That is, the work function metal layer 130 will contact oxygen as little as possible, so that the thickness of the oxide layer between the work function metal layer 130 and the stop layer 140 caused by the oxidation of the work function metal layer 130 is as thin as possible. In this embodiment, the work function metal layer 130 is a titanium aluminum metal layer hence the oxide layer of the work function metal layer 130 is a titanium aluminum oxide layer, and the thickness of the titanium aluminum oxide layer is at least less than 30% of the thickness of the titanium aluminum metal layer 130. In a preferred embodiment, the thickness of the titanium aluminum oxide layer can approach zero, meaning that the titanium aluminum oxide layer will not be generated on the surface of the work function metal layer 130.

It is worthy of note that the surface of the titanium aluminum metal layer 130 will generate the oxide layer if the metal gate 100 is exposed into an oxygen containing environment, or an annealing process is performed after the titanium aluminum metal layer 130 is formed. Even if the metal gate 100 is just exposed into the atmosphere, the oxygen in the atmosphere would oxidize the titanium aluminum metal layer 130, and the thickness of the native titanium aluminum oxide layer is thicker than 35% of the titanium aluminum metal layer 130. The metal such as aluminum of the work function metal layer 130 would be trapped by the oxide layer and avoid the metal diffusing downwards, resulting in the higher work function of the metal gate 100. In the present invention, the stop layer 140 is formed in-situ, therefore the thickness of the oxide layer generated by the oxidation of the work function metal layer 130 decreases, resulting in the reduction of the work function of the metal gate 100. This improves the electrical quality of devices applying the metal gate 100, such as MOS transistor, and particularly for NMOS transistors.

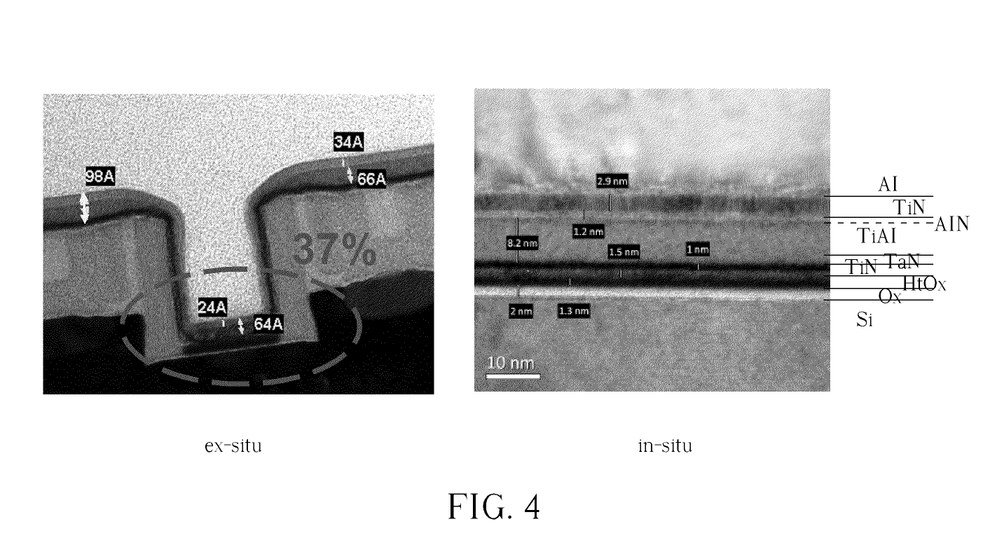

For instance, as shown in FIG. 4, in an NMOS embodiment measured by the transmission electron microscope (TEM), the thickness of the oxide layer can substantially approach zero under an oxygen-free environment. That is, the thickness of the oxide layer can substantially approach zero in the process where the stop layer 140 is formed in-situ (as shown in the right diagram), and the work function of the metal gate 100 can achieve 3.9˜4.5 eV. Compared with the prior art process, which exposes the metal gate 100 into an oxygen-containing environment, the thickness of the native oxide layer is up to 24 angstrom, which is 37% of the thickness of the work function metal layer (as shown in the right diagram) and the work function is up to 4.81 eV. It can be proved by the TEM measurement that the present invention can reduce the thickness of the oxide layer, thereby decreasing the work function of the metal gate 100, and enhance the electrical quality of the N-typed metal gate 100. Furthermore, as shown in FIG. 4, in an embodiment of the stop layer 140 is a titanium nitride layer and the work function metal layer 130 is a titanium aluminum metal layer, nitrogen gas is imported while the titanium nitride layer is formed in-situ, so that the surface of the titanium aluminum metal layer is nitridized and transforms to an aluminum nitride layer 150.

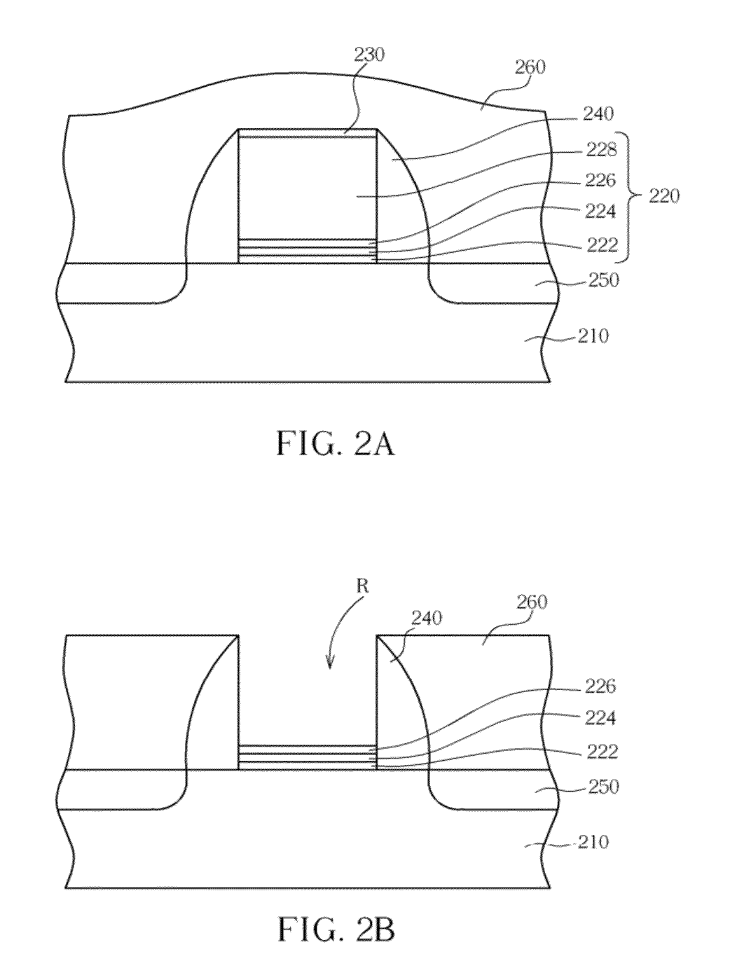

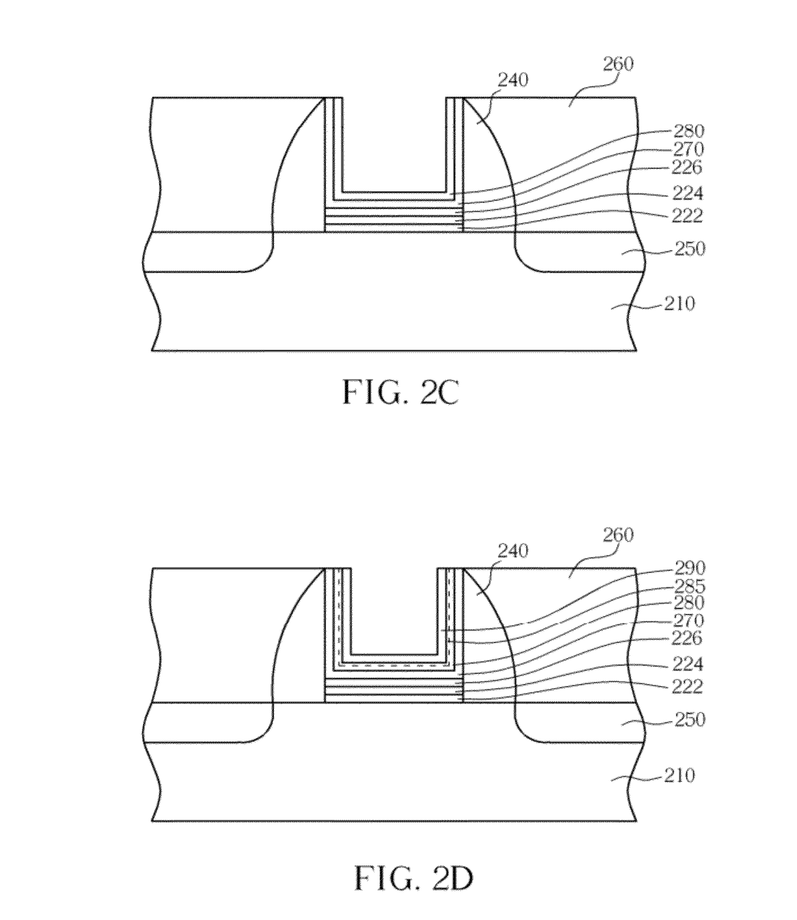

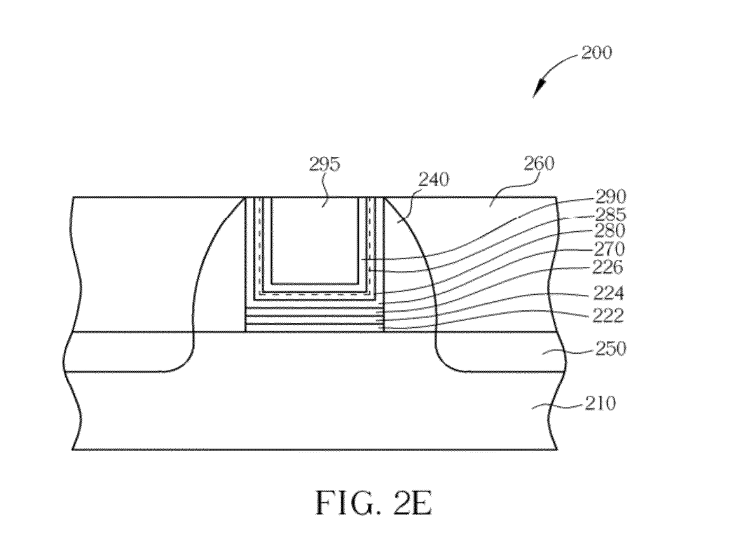

FIG. 2A-2E schematically depicts a cross-sectional view of a metal gate process according to the second embodiment of the present invention, wherein the aforementioned metal gate is applied to a gate last for high-k first process in this embodiment. The metal gate and fabrication method thereof in this invention may also be applied to another semiconductor processes, and is not limited thereto. Please refer to 2A-2E. As shown in FIG. 2A, an interface layer 222, used as a buffer layer, is selectively formed on a substrate 210 and a gate dielectric layer 224 is formed thereon, wherein the materials of said components are the same as the first embodiment (as shown in FIG. 1A-1B). For instance, the interface layer 222 may be a silicon dioxide layer, and the gate dielectric layer 224 may be a dielectric layer having a high dielectric constant, but this is not limited thereto. A first barrier layer 226 is selectively formed on the gate dielectric layer 224, and the first barrier layer 226 may include at least one of a titanium nitride layer and a tantalum nitride layer. Thereafter, a sacrificed gate 228 is formed on the first barrier layer 226. In doing so, a gate structure 220 at least having a gate dielectric layer 224 and a sacrificed gate 228 is formed. The said interface layer 222, gate dielectric layer 224, first barrier layer 226 and sacrificed gate 228 are patterned to form the gate structure 220. In one case, a cap layer (not shown) may be selectively formed on the sacrificed gate (not shown) and a photo-etching process is applied to pattern the cap layer 230 and then the patterned cap layer 140 is applied as an etching mask to sequentially form sacrificed gate 228 the first barrier layer 226, the gate dielectric layer 224 and the interface layer 222. Thereafter, a spacer 240 is formed beside the gate structure 220, wherein the spacer 240 may be a single or multi-composite structure. In an embodiment, an ion implantation process and junction activation annealing process etc. are performed to form a source/drain region 250 next to the spacer 240 by using the gate structure 220 and the spacer 240 as masks. Otherwise, a silicon epitaxial process may be selectively performed and a metal silicide process, a contact etch stop layer (CESL) process etc. may be performed on the source/drain region 250. Thereafter, a dielectric layer 260 is formed and covers the substrate 210, the cap layer 230 and the spacer 240 (as shown in FIG. 2A).

As shown in FIG. 2B, the dielectric layer 260 and the cap layer 230 are removed by polishing methods, such as chemical mechanical polishing process (CMP), to expose the sacrificed gate 228. The sacrificed gate 228 is removed by methods, such as dry etching process or wet etching process, to form the recess R and expose the first barrier layer 226. The sacrificed gate 228 may be composed of polycrystalline silicon or other materials in this embodiment, and the first barrier layer 226 may be, but is not limited to, a titanium nitride layer used as an etching stop layer to prevent the gate dielectric layer 224 beneath the first barrier layer 226 from being damaged in the process. This also means the first barrier layer 226 can avoid the ingredients of materials formed thereon diffusing down to the gate dielectric layer 224.

As shown in FIG. 2C, a second barrier layer 270 is selectively formed on the first barrier layer 226 in the recess R. The material of the second barrier layer 270 may be a tantalum nitride layer in this embodiment, but the material of the second barrier layer 270 may be another material in another embodiment. A work function metal layer 280 is formed on the second barrier layer 270 in the recess R. In this embodiment, the work function metal layer 280 is a titanium aluminum metal generally used as the work function metal layer forming gate of NMOS transistor, but the work function metal layer 280 may also be another metal layer in another embodiment applied to form another structure such as a PMOS transistor etc., but is not limited thereto.

As shown in FIG. 2D, a stop layer 290 is formed in-situ on the work function metal layer 280 in the recess R in an oxygen-free environment. Finally, as shown in FIG. 2E, a main metal electrode 295 is formed on the stop layer 290 by a polishing process, and then the gate last for high-k first process is finished, meaning the transistor 200 is formed. This embodiment is for NMOS transistors, but another embodiment may be for semiconductor components such as PMOS transistors or CMOS transistors. In this embodiment, the main metal electrode 295 is an aluminum metal electrode and the stop layer 290 is a titanium nitride layer for preventing aluminum in the main metal electrode 295 thereon from diffusing downward and polluting the underlying gate structure, in particular polluting the gate dielectric layer 224 which would result in the lower electrical quality of the transistor 200. Otherwise, the dielectric layer 260, the contact etch stop layer (CESL) and etc are selectively removed and then a dielectric layer and a contact etch stop layer (CESL) may be reformed to enhance the electrical performance of MOS transistor.

Due to the stop layer 290 being formed in-situ on the work function metal layer 280 (in other words, the stop layer 290 is not formed after exposing the metal gate into the atmosphere or performing the oxygen-importing process applied in the prior art), the thickness of the oxide layer in this invention generated by the oxidation of the work function metal layer 280 is less than 30% of the thickness of the work function metal layer 280. In a preferred embodiment, the thickness of the oxide layer is substantially close to zero.

Furthermore, as shown in FIG. 2D, in an embodiment of the stop layer 290 is a titanium nitride layer and the work function metal layer 280 is a titanium aluminum metal layer, nitrogen gas is imported while the titanium nitride layer is formed in-situ, so that the surface of the titanium aluminum metal layer is nitridized and transforms to an aluminum nitride layer 285.

In this way, the work function of the transistor 200 decreases and the electrical quality of the transistor 200 increases. In a preferred embodiment, the work function of the transistor 200 can achieve 3.9˜4.5 eV.

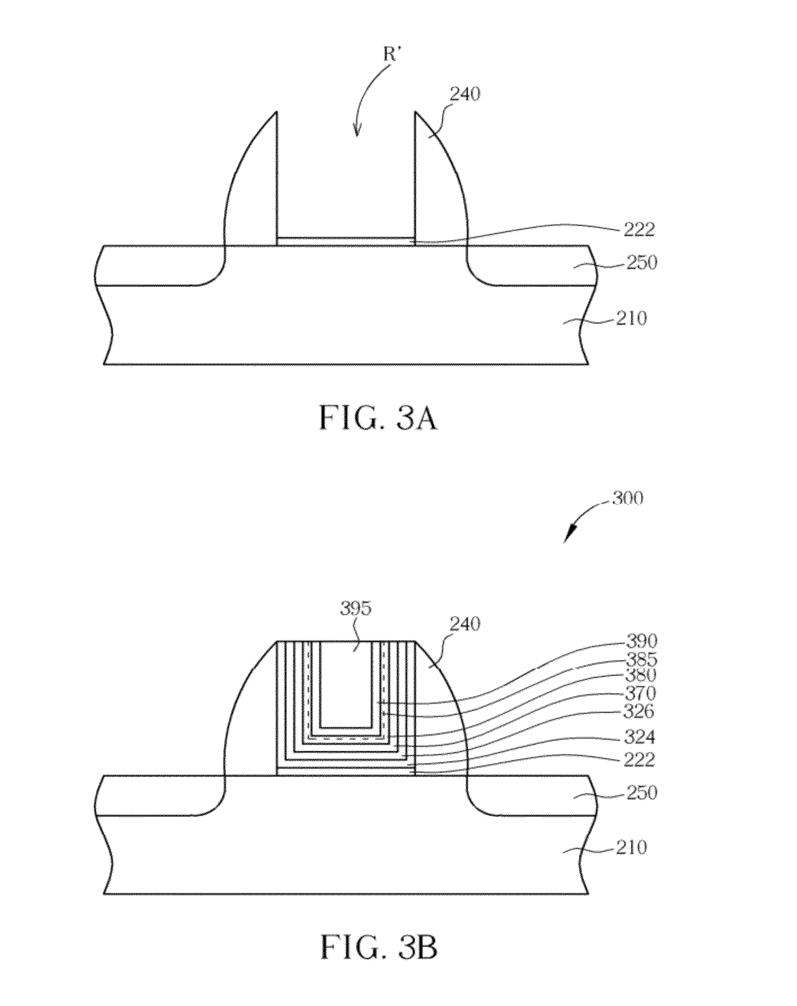

FIG. 3A-3B schematically depicts a cross-sectional view of a metal gate process according to the third embodiment of the present invention, wherein the metal gate and fabrication method thereof in the first embodiment is applied to the gate last for high-k last process in this embodiment. For simplifying and describing this embodiment specifically, symbols in the third embodiment are common with symbols in the second embodiment for representing common objects.

The forepart process of this embodiment is the same as the forepart process of the second embodiment as shown in FIG. 2A. The difference between this embodiment and the second embodiment is: the gate dielectric layer 224 of the second embodiment is a dielectric layer having a high-k constant, but in this embodiment, a sacrificed gate dielectric layer 224 having materials that meet the characteristics of low cost, ease of etching and ease of depositing are formed after the interface layer 222 is formed. Thereafter, the first barrier layer 226 is selectively formed, and then the sacrificed gate 228, the spacer 240, the source/drain region 250, the dielectric layer 260 on the substrate 210, the cap layer 230 and the spacer 240 are sequentially formed. As shown in FIG. 3A, the cap layer 230 is polished so that the sacrificed gate 228 is exposed, and then the etching process is performed to sequentially etch the sacrificed gate 228, the first barrier layer 226 and the gate dielectric layer 224 to form a recess R′, therefore leaving the interface layer 222, used as a etch stop layer, on the substrate 210.

As shown in FIG. 3B, a gate dielectric layer 324, a first barrier layer 326, a second barrier layer 370 and a work function metal layer 380 are sequentially refilled in the recess R′. A stop layer 390 is formed in-situ on the surface of the work function metal layer 380 without exposing the work function metal layer 380 into the atmosphere or an oxygen-containing environment. A main metal gate 395 is formed and polished. The gate dielectric layer 324 may be gate dielectric layer having a high dielectric constant, the first barrier layer 326 may be a titanium nitride layer, the second barrier layer 370 may be a tantalum nitride layer, the work function metal layer 380 may be a titanium aluminum metal layer applied in an NMOS transistor, the stop layer 390 may be a titanium nitride layer, and the main metal gate 395 may be an aluminum gate, but they are not limited thereto. In this case, the barrier layer is a multi-layer structure including the first barrier layer 326 and the second barrier layer 370, but the barrier layer may be also a single layer structure.

Compared to the second embodiment, the gate dielectric layer 324, the first barrier layer 326, the second barrier layer 370, the work function metal layer 380 and the stop layer 390 in this embodiment have a U-shaped cross-sectional profile. Likewise, a silicon epitaxial process is selectively performed and a metal silicide process, a contact etch stop layer (CESL) process etc. may be performed on the source/drain region. That is, the gate last for high-k last process of this embodiment is finished; meaning the transistor 300 of the third embodiment is formed. Due to the stop layer 390 also being formed in-situ on the work function metal layer 380, the oxidation of the surface of the work function metal layer 380 in this embodiment can also be retarded, therefore the thickness of the oxide layer is less than 30% of the thickness of the work function metal layer 380. In a preferred embodiment, the thickness of the oxide layer can be substantially close to zero, and the work function of the transistor 300 in this invention can achieve 3.9˜4.5 eV.

Furthermore, as shown in FIG. 3B, in an embodiment of the stop layer 390 is a titanium nitride layer and the work function metal layer 380 is a titanium aluminum metal layer, nitrogen gas is imported while the titanium nitride layer is formed in-situ, so that the surface of the titanium aluminum metal layer is nitridized and transforms to an aluminum nitride layer 385.

Above all, because the stop layer is formed in-situ on the work function metal layer without exposing the work function metal layer to the atmosphere or an oxygen-containing environment, the thickness of the oxide layer between the stop layer and the work function metal layer generated by the oxidation of the work function metal layer can decrease. Specifically, the thickness of the oxide layer is less than 30% of the thickness of the work function metal layer. In a preferred embodiment, the thickness of the oxide layer can approach to zero. Compared to the work function metal gate of the prior art, where thickness of the oxide layer generated by the oxidation of the work function metal layer is more than 35% of the thickness of the work function metal layer, and the work function of the metal gate structure formed by the process of this invention can achieve 3.9˜4.5 eV, the work function of the metal gate in this invention is lower so that the electrical quality of the metal gate is improved.

Those skilled in the art will readily observe that numerous modifications and alterations of the device and method may be made while retaining the teachings of the invention.

What is claimed is:

1. A metal gate, comprising:
a substrate:
a gate dielectric layer located on the substrate;
a work function metal layer located on the gate dielectric layer;
an aluminum nitride layer located on the work function metal layer; and
a stop layer located on the aluminum nitride layer.

2. The metal gate of claim 1, wherein the metal gate comprises a metal gate of an NMOS transistor.

3. The metal gate of claim 1, wherein the gate dielectric layer comprises a dielectric layer having a high dielectric constant.

4. The metal gate of claim 1, wherein the metal gate further comprises a barrier layer located between the gate dielectric layer and the work function metal layer.

5. The metal gate of claim 1, wherein the stop layer comprises a titanium nitride layer.

6. The metal gate of claim 1, wherein the work function of the metal gate is about 3.9˜4.5 eV.

7. A fabricating method for a metal gate, comprising:
forming a gate dielectric layer on a substrate;
forming a work function metal layer on the gate dielectric layer; and
forming in-situ a stop layer on the work function metal layer.

8. The fabricating method for a metal gate of claim 7, wherein the metal gate comprises a metal gate of an NMOS transistor.

9. The fabricating method for a metal gate of claim 7, wherein the stop layer comprises a titanium nitride layer.

10. The fabricating method for a metal gate of claim 7, further comprising:
after forming the gate dielectric layer on the substrate, forming a barrier layer.

11. The fabricating method for a metal gate of claim 7, wherein the work function of the metal gate is about 3.9˜4.5 eV.

12. A fabricating method for a metal gate, comprising:
forming a gate structure on a substrate, wherein the gate structure comprises a gate dielectric layer and a sacrificed gate located on the gate dielectric layer;
performing an etching process to remove the sacrificed gate;
forming a work function metal layer to replace the sacrificed gate; and
forming in-situ a stop layer on the work function metal layer.

13. The fabricating method for a metal gate of claim 12, wherein the metal gate comprises a metal gate of a NMOS transistor.

14. The fabricating method for a metal gate of claim 12, wherein the gate dielectric layer comprises a dielectric layer having a high dielectric constant.

15. The fabricating method for a metal gate of claim 12, wherein the work function metal layer further comprises a titanium aluminum metal layer.

16. The fabricating method for a metal gate of claim 12, wherein the work function of the metal gate is about 3.9˜4.5 eV.

17. The fabricating method for a metal gate of claim 12, further comprising:
after removing the sacrificed gate, removing the gate dielectric layer and then forming a dielectric layer having a high dielectric constant.

18. The fabricating method for a metal gate of claim 12, after forming the gate structure on the substrate, further comprising:
forming a spacer on the sidewalls of the gate structure.
